(19) United States
(12) Patent Application Publication
(10) Pub. No.: US 2026/0299379 A1
(43) Pub. Date: Oct. 1, 2026

(54) IMAGING DEVICE AND HOME APPLIANCE HAVING THE SAME (As Amended)

(71) Applicant: LG ELECTRONICS INC., Seoul (KR)

(72) Inventor: Wontae KIM, Seoul (KR)

(21) Appl. No.: 19/489,006

(22) PCT Filed: Mar. 22, 2024
(86) PCT No.: PCT/KR2024/003610

§ 371 Date: Dec. 1, 2025

(30) Foreign Application Priority Data
Jun. 1, 2023 (KR) 10-2023-0070898

(51) Int. Cl. G03B 17/55; G03B 11/04; G03B 17/12; G03B 30/00; H05K 7/20

(52) U.S. Cl. CPC G03B 17/55; G03B 11/043; G03B 17/12; G03B 30/00; H05K 7/20172

(57) ABSTRACT

Disclosed are an invention pertaining to an imaging device and a home appliance having same. The disclosed invention has a camera module and a fan accommodated in an accommodation space inside a case, wherein a first surface disposed on one side in a first direction of the case opens the accommodation space in the first direction, and the fan generates an air flow passing through the first surface in the first direction.

### TECHNICAL FIELD

The present disclosure relates to an imaging device, and in particular, to an imaging device disposed above a cooktop and a home appliance including the same

### BACKGROUND

A cooking appliance is one of home appliances for cooking food, which is installed in a kitchen space and cooks food according to a user's intention. Such cooking appliances can be classified in various ways according to a heat source or form used or a type of fuel.

When cooking appliances are classified according to a form of cooking food, they can be classified into open-type and sealed-type cooking appliances according to a form of a space where food is placed. Sealed-type cooking appliances include ovens, microwave ovens, and the like, and open-type cooking appliances include cooktops, hoods, and the like.

A sealed-type cooking appliance is a cooking appliance that shields a space where food is located and heats the shielded space to cook the food. In the sealed-type cooking appliance, a chamber, i.e., a cooking chamber, which is a space that is shielded when food is placed and the food is to be cooked, is provided inside a main body. Such a cooking chamber becomes a space where food is substantially cooked. A heat source is provided in an internal or external space of the cooking chamber to heat the cooking chamber.

Among sealed-type cooking appliances, a microwave oven is a cooking device that generates microwaves using electricity and penetrates a cooking target accommodated in the cooking chamber to heat the cooking target by causing molecular motion therein.

A microwave oven is a kitchen appliance that irradiates high frequency waves from a magnetron to a cooking object to simultaneously heat an inside and an outside thereof, has high thermal efficiency to significantly shorten a cooking time of the cooking object, can reduce loss of nutritional value in a process of cooking, thawing, and heating the cooking object, and is widely used due to advantages such as being able to directly cook the cooking object while the cooking object is stored in a container.

Recently, an over-the-range microwave oven having a hood function, also known as an OTR (Over the Range) type microwave oven, has been released. The over-the-range microwave oven is provided in a form that combines a general cooking function and a hood function of a microwave oven.

Such an over-the-range microwave oven is installed above a cooktop to be spaced apart from the cooktop by a predetermined distance, and can suck and discharge contaminated air containing contaminants such as odors and smoke generated in a process of cooking on the cooktop.

Recently, an over-the-range microwave oven having a camera has been developed. Such an over-the-range microwave oven can photograph a cooktop using a camera, and an image acquired by the camera can be used to monitor an operating state of the cooktop.

Additionally, a result of monitoring the operating state of the cooktop using the image can be used to control a hood operation of the over-the-range microwave oven or can be used to control an operation of the cooktop.

The camera is disposed above the cooktop and photographs the cooktop while looking down at the cooktop from above the cooktop. In the over-the-range microwave oven, the camera is mainly installed on a bottom surface of the over-the-range microwave oven.

Contaminated air generated in a process of cooking on the cooktop can be sucked into an inside of the over-the-range microwave oven through an intake port and then discharged to an outside of the over-the-range microwave oven through a discharge port. The intake port is disposed on the bottom surface of the over-the-range microwave oven, and the discharge port can be disposed on an upper surface of the over-the-range microwave oven.

Like the intake port, the camera is mainly installed on the bottom surface of the over-the-range microwave oven, and thus is disposed at a position adjacent to the intake port. That is, the camera is disposed on a flow path of contaminated air flowing from the cooktop toward the intake port, and thus the camera is inevitably exposed to an environment affected by heat and an environment in contact with water vapor and oil vapor.

In an environment where the camera is exposed to heat, water vapor, and oil vapor, a possibility of malfunction or failure of the camera increases due to an influence of heat, and image quality of an image acquired by the camera is degraded due to water vapor or oil vapor, or a possibility of malfunction or failure of the camera increases.

Additionally, when the camera is contaminated due to water vapor or oil vapor, camera cleaning work must be performed, and frequent camera cleaning work is very cumbersome, and when the camera is built into the over-the-range microwave oven, there are many difficulties in performing maintenance work such as camera cleaning work.

### SUMMARY

### Technical Problems

One objective of the present disclosure is to provide an imaging device having an improved structure so as to be less affected by heat, water vapor, and oil vapor, and a home appliance having the same.

Another objective of the present invention is to provide an imaging device having an improved structure so that maintenance work can be easily performed, and a home appliance having the same.

### Technical Solutions

An imaging device according to an embodiment of the present invention for achieving the object accommodates a camera module and a fan in an accommodation space inside a case, wherein a first surface disposed on one side in a first direction of the case opens the accommodation space in the first direction, and the fan generates an air flow passing through the first surface in the first direction.

Accordingly, contaminated air can be prevented from approaching the imaging device by forming an air flow that blocks a path through which the contaminated air approaches the imaging device.

In another form of the present invention, a camera module and a fan are accommodated inside a case, and air sucked by the fan is discharged to the periphery of the camera module.

In another form of the present invention, a camera module and a fan are accommodated inside a case, the fan sucks and discharges air through an intake port and a discharge port formed in the case, and intake ports are formed on two or more surfaces in different directions.

An imaging device according to an aspect of the present invention includes: a case forming an accommodation space therein; a camera module accommodated in the accommodation space; and a fan generating an air flow passing through the accommodation space.

Preferably, the case is provided with a first surface disposed on one side of the accommodation space in a first direction and opening the accommodation space in the first direction, and the fan can generate an air flow passing through the first surface in the first direction.

Preferably, the first surface is provided with a discharge port forming a passage penetrating the first surface in the first direction.

Preferably, in the first direction, the camera module is disposed between the fan and the discharge port.

Additionally, the imaging device may further comprise an outer tube portion surrounding the discharge port from a radially outer side of the discharge port.

Preferably, the outer tube portion is formed such that an inside of the outer tube portion narrows toward a radial center of the outer tube portion toward one side in the first direction.

Preferably, an inner circumferential surface of the outer tube portion is formed to be inclined toward a centripetal direction toward one side in the first direction.

Additionally, the first surface may be provided with a penetrating portion penetrating a portion of the first surface in the first direction.

Preferably, the penetrating portion includes a light-transmitting hole that forms, in the first surface, a passage for light to reach the camera module.

Additionally, the penetrating portion may include a discharge port forming a passage penetrating the first surface in the first direction.

Preferably, on a plane orthogonal to the first direction, the discharge port is disposed on an outer side of the light transmission hole.

The imaging device may further include an outer tube portion surrounding the light transmission hole from a radially outer side thereof, and an inner tube portion surrounding the light transmission hole from a radially outer side thereof and disposed radially inside the outer tube portion.

Preferably, the discharge port is disposed between the inner tube portion and the outer tube portion.

Preferably, the inner tube portion protrudes from the first surface toward the accommodation space in the first direction, and at least a portion of the camera module is accommodated inside the inner tube portion.

Additionally, the imaging device may further comprise a lens cover covering the light transmission hole and coupled to the inner tube portion.

Preferably, the lens cover may be provided to be capable of allowing light to pass therethrough.

Preferably, the case is provided with a second surface disposed on the other side in the first direction of the accommodation space, and the second surface is provided with an intake port forming a passage penetrating the second surface in the first direction.

Preferably, the first surface is provided with a discharge port forming a passage penetrating the first surface in the first direction, the intake port and the discharge port are arranged along the first direction, and the fan is disposed between the intake port and the discharge port.

Additionally, the case may be provided with a second surface disposed on the other side in the first direction of the accommodation space, and a third surface connecting between the first surface and the second surface.

Additionally, the third surface may be provided with an intake port forming a passage penetrating the third surface in a direction orthogonal to the first direction.

Additionally, a home appliance according to another aspect of the present invention may comprise: a hood module disposed above a cooktop including at least one burner and sucking vapor flowing upward above the cooktop; a camera photographing a set area disposed between the hood module and the cooktop; and a control unit calculating an amount of vapor in the set area based on a photographed image which is an image acquired by the camera and changing an operating state of the hood module according to the calculated amount of vapor.

Additionally, the home appliance may further comprise a main body including a cooking chamber provided therein and a heating unit heating the cooking chamber.

Preferably, the hood module is disposed inside the main body.

### Advantageous Effects

According to the present invention, it is possible to prevent contaminated air from approaching the imaging device by discharging a discharge air flow on a path along which the contaminated air approaches the imaging device, thereby protecting the imaging device from heat, water vapor, and oil vapor contained in the contaminated air.

Additionally, according to the present invention, by enabling smooth inflow of air through an intake port regardless of which surface of the imaging device is installed on a home appliance, it is possible to provide an effect of being freely installable on a home appliance without being restricted by an installation position or direction.

### BRIEF DESCRIPTION OF DRAWINGS

The accompanying drawings constitute a part of the specification, illustrate one or more embodiments in the disclosure, and together with the specification, explain the disclosure, wherein:

FIG. 1 is a perspective view illustrating an imaging device according to one embodiment of the present invention.

FIG. 2 is an exploded perspective view illustrating a disassembled state of the imaging device illustrated in FIG. 1.

FIG. 3 is a cross-sectional view showing an internal structure of the imaging device illustrated in FIG. 1.

FIG. 4 is a rear view illustrating a rear surface of the imaging device illustrated in FIG. 1.

FIG. 5 is a side view illustrating a side surface of the imaging device illustrated in FIG. 1.

FIG. 6 is a cross-sectional view showing one example of an air flow generated by the imaging device illustrated in FIG. 1.

FIG. 7 is a cross-sectional view showing another example of an air flow generated by the imaging device illustrated in FIG. 1.

FIG. 8 is a perspective view showing one example in which the imaging device is installed in a home appliance.

FIG. 9 is a side view illustrating a side surface of the home appliance illustrated in FIG. 8.

FIG. 10 is a perspective view showing another example in which the imaging device is installed in a home appliance.

FIG. 11 is a side view illustrating a side surface of the home appliance illustrated in FIG. 10.

FIG. 12 is a cross-sectional view showing an internal structure of an imaging device according to another embodiment of the present invention.

FIG. 13 is a cross-sectional view showing another example of an air flow generated by the imaging device illustrated in FIG. 12.

### DETAILED DESCRIPTION

The above-described objectives, features and advantages are specifically described hereafter with reference to accompanying drawings such that one having ordinary skill in the art to which the invention pertains can easily embody the technical spirit of the disclosure easily. In describing the invention, the detailed description of known technologies in relation to the subject matter of the disclosure is omitted if it is deemed that it makes the gist of the invention unnecessarily vague. Hereinafter, preferred embodiments according to the invention are specifically described with reference to the accompanying drawings. In the drawings, identical reference numerals can denote identical or similar components.

The terms “first”, “second” and the like are used herein to describe various components, but the components are not to be limited by the terms. The terms are used only to distinguish one component from another component. Certainly, a first component can be a second component, unless stated to the contrary.

The invention is not limited to the embodiments set forth herein, and can be modified and changed in various different forms. However, the embodiments are provided such that the disclosure of the invention can be thorough and complete and fully convey its scope to one having ordinary skill in the art. Accordingly, the invention is to be understood to include all modifications, equivalents or replacements within the technical spirit and scope of the disclosure, including a replacement of the configuration of any one embodiment with the configuration of another embodiment or an addition of the configuration of any one embodiment to the configuration of another embodiment.

The accompanying drawings are provided for a better understanding of the embodiments set forth in the disclosure and are not intended to limit the technical spirit disclosed in the specification. It is to be understood as including all modifications includes all modifications, equivalents or replacements. The sizes or thicknesses of the components in the drawings can be exaggerated or reduced for ease of understanding and the like. However, the protection scope of the invention is not to be interpreted in a limited way due to this.

The terms used in the disclosure are used only to describe specific embodiments or examples and not intended to limit the disclosure. In the disclosure, singular forms include plural forms as well, unless explicitly indicated otherwise. In the disclosure, the terms “comprise”, “comprised of” and the like specify the presence of stated features, integers, steps, operations, elements, components or combinations thereof but do not imply the exclusion of the presence or addition of one or more other features, integers, steps, operations, elements, components or combinations thereof.

The terms including ordinal numbers such as “first”, “second” and the like can be used to describe various components, but the components are not to be limited by the terms. The terms are used only to distinguish one component from another component.

When any one component is described as “connected” or “coupled” to another component, it is to be understood that it can be directly connected or coupled to the other component, but another component can also exist in between. On the other hand, when any one component is described as “directly connected” or “directly coupled” to another component, it is to be understood that no other component exists in between.

When any one component is described as being “on (or under)” another component, any one component can be directly on (or under) another component, and an additional component can be interposed between the two components, it is to be understood.

Unless otherwise defined, all the terms including technical or scientific terms used herein have the same meaning as commonly understood by one having ordinary skill in the art to which the disclosure pertains. Additionally, terms such as those defined in commonly used dictionaries are to be interpreted as having a meaning that is consistent with their meaning in the context of the relevant art, and unless explicitly defined herein, are not to be interpreted in an ideal way or an overly formal way.

In the state where a home appliance such as a cooking appliance stands on the floor, a direction in which a door is installed with respect to the center of the home appliance is defined as a forward direction. Accordingly, a direction of entering into an inside of the home appliance with the door open is a rearward direction. For convenience, the direction toward the front and the rear (i.e., the front-rear direction) may be referred to as a first direction. Then the forward direction can be referred to as one direction of the first direction, and the rearward direction can be referred to as the other direction of the first direction.

Additionally, a gravitational direction can be defined as a downward direction, and a direction opposite to the gravitational direction can be defined as an upward direction.

Further, a horizontal direction orthogonal to a front-rear direction of the home appliance, i.e., a widthwise direction of the home appliance when viewing the home appliance in front of the home appliance, can be referred to as a left-right direction. For convenience, the left-right direction can be referred to as a second direction. Then the right side can be referred to as one direction of the second direction, and the left side can be referred to as the other direction of the second direction.

Further, the widthwise direction of the home appliance can also be referred to as a lateral direction. Then the right side can be referred to as one side of the lateral direction, and the left side can be referred to as the other side of the lateral direction.

Additionally, the up-down direction can be referred to as a third direction. Then an upward direction can be referred to as one direction of the third direction, and a downward direction can be referred to as the other direction of the third direction.

Furthermore, the up-down direction can be referred to as a vertical direction. Then the front-rear direction and the left-right direction, i.e., the first direction and the second direction, can be referred to as the horizontal direction, including them.

Throughout the disclosure, the terms “A and/or B” as used herein can denote A, B or A and B, and the terms “C to D” can denote C or greater and D or less, unless stated to the contrary.

### Overall Structure of Imaging Device

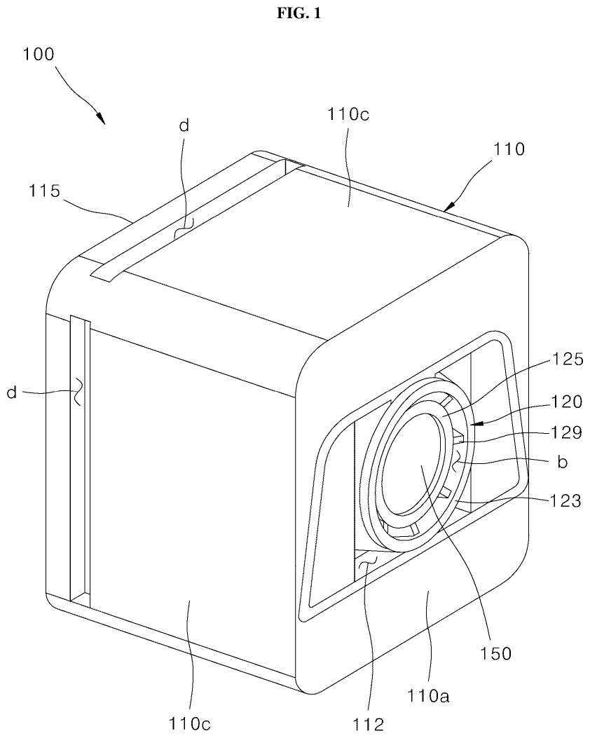

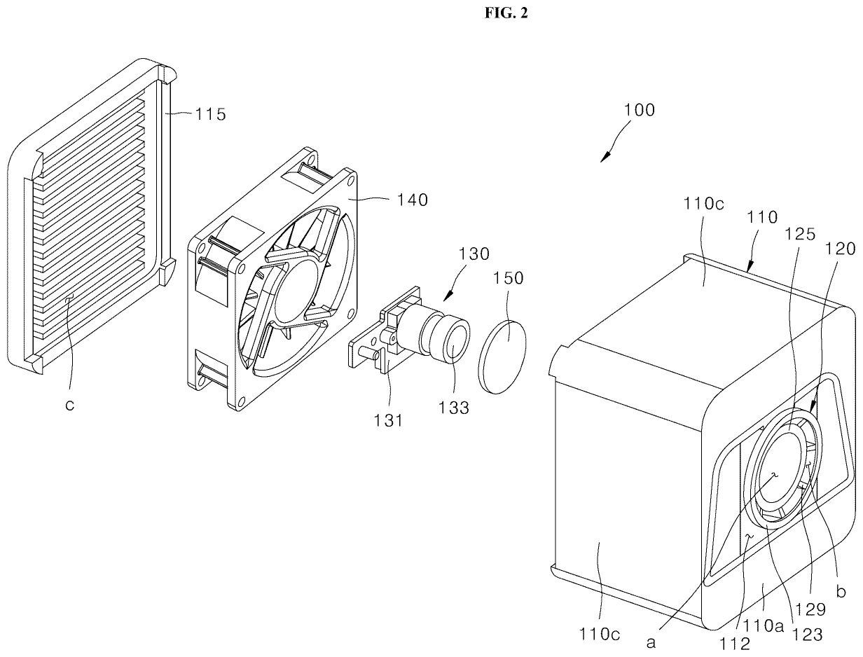

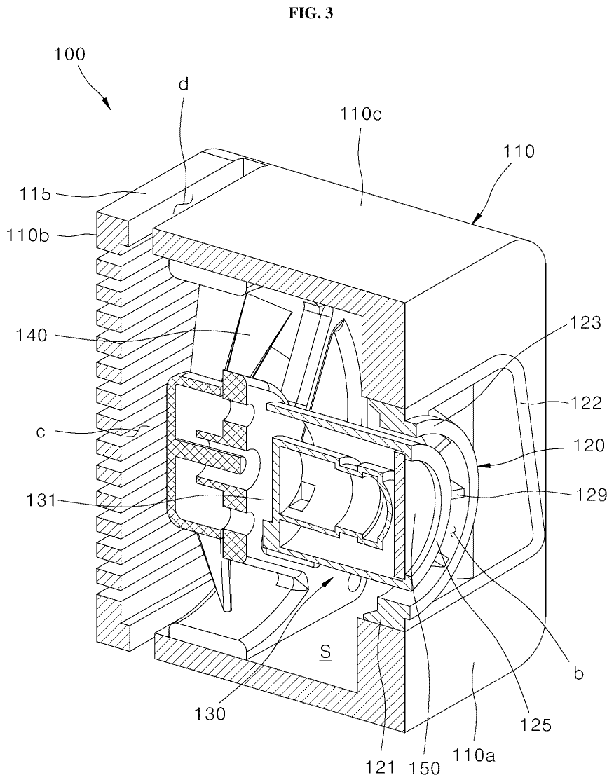

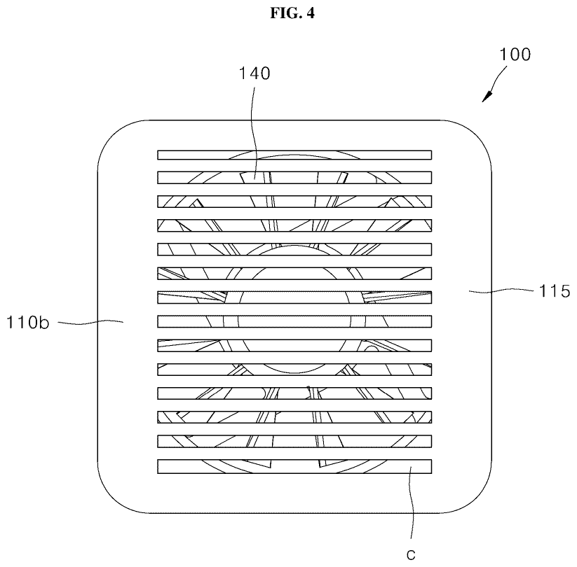

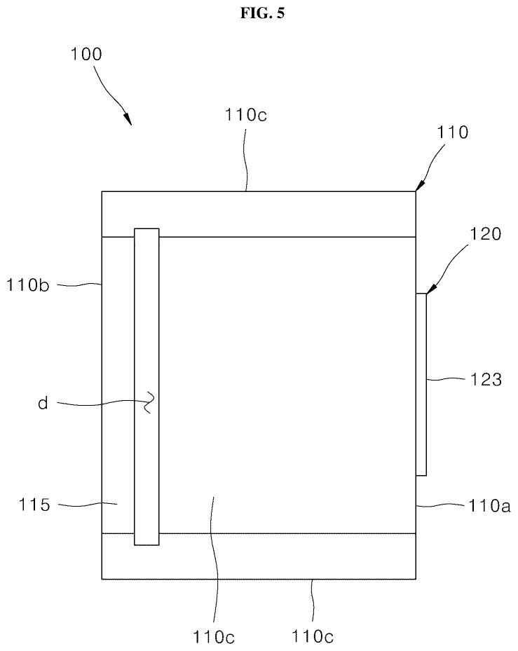

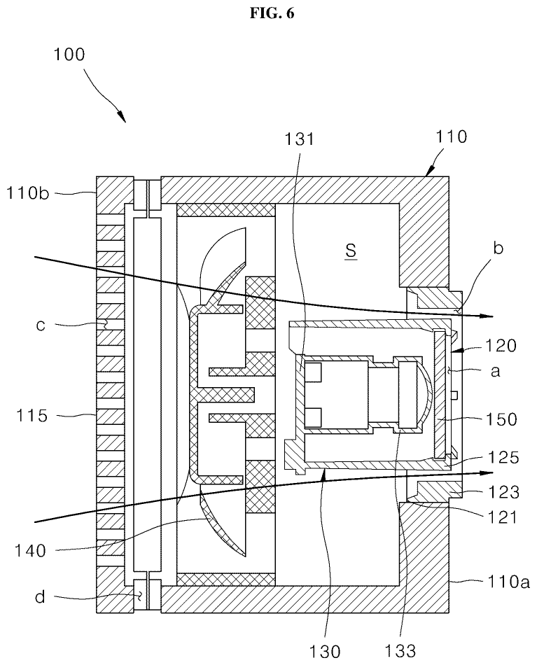

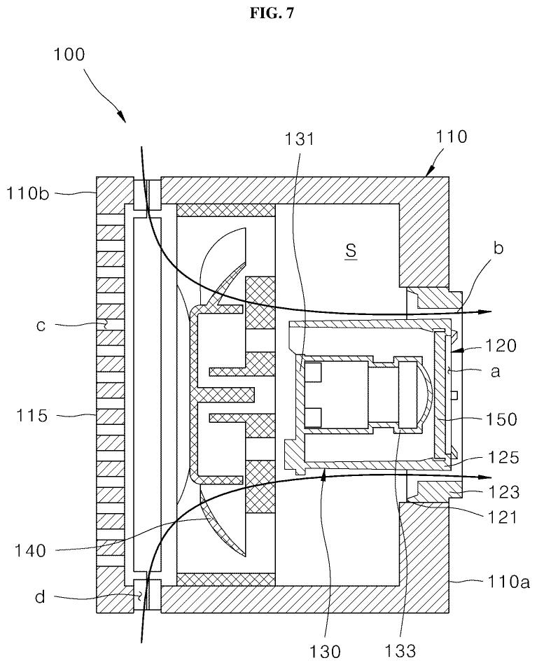

FIG. 1 is a perspective view illustrating an imaging device according to one embodiment of the present invention, FIG. 2 is an exploded perspective view illustrating a disassembled state of the imaging device illustrated in FIG. 1, and FIG. 3 is a cross-sectional view showing an internal structure of the imaging device illustrated in FIG. 1. Additionally, FIG. 4 is a rear view illustrating a rear surface of the imaging device illustrated in FIG. 1, and FIG. 5 is a side view illustrating a side surface of the imaging device illustrated in FIG. 1. Additionally, FIG. 6 is a cross-sectional view showing one example of an air flow generated by the imaging device illustrated in FIG. 1, and FIG. 7 is a cross-sectional view showing another example of an air flow generated by the imaging device illustrated in FIG. 1.

Referring to FIGS. 1 to 3, an imaging device 100 according to one embodiment of the present invention may include a case 110.

The case 110 forms an exterior of the imaging device 100. An accommodation space S can be formed inside the case 110. Main components constituting the imaging device 100, such as a camera module 130 and a fan 140 to be described later, can be accommodated inside the case 110, i.e., in the accommodation space S.

The case 110 may be provided with a first surface 110a. The first surface 110a may be disposed on one side of the accommodation space S in the first direction.

As one example, the first surface 110a can be disposed on a front side of the accommodation space S. Such a first surface 110a can form a front surface of the case 110, and at least a portion of the first surface 110a can open the accommodation space S in the first direction.

For example, the first surface 110a forms a front exterior of the case 110 and may block the front side of the accommodation space S, and a portion of the first surface 110a can open the accommodation space S forward.

The case 110 may be provided with a second surface 110b. The second surface 110b can be disposed on the other side in the first direction of the accommodation space S. As one example, the second surface 110b can be disposed on a rear side of the accommodation space S. That is, the first surface 110a and the second surface 110b can be disposed in a front-rear direction with the accommodation space S interposed therebetween.

Such the second surface 110a can form a rear surface of the case 110, and at least a portion of the second surface 110b can open the accommodation space S in the first direction.

For example, the second surface 110b forms a rear exterior of the case 110 and can block the rear side of the accommodation space S, and a portion of the second surface 110b can open the accommodation space S rearward.

Additionally, the case 110 may be provided with a third surface 110c. The third surface 110c can connect between the first surface 110a and the second surface 110b. Such a third surface 110c can be disposed on at least any one of a portion above the accommodation space S, a portion below the accommodation space S, and portions on both sides of the accommodation space S.

As one example, the third surface 110c can be disposed on each of a portion above the accommodation space S, a portion below the accommodation space S, and both side portions of the accommodation space S. That is, the third surface 110c can form an exterior of an upper surface, a bottom surface, and both side surfaces of the case 110.

In the present embodiment, the case 110 is illustrated as being formed in a hexahedral shape. According to this, the first surface 110a forms a front exterior of the case 110, and the second surface 110b can form a rear exterior of the case 110. Additionally, the third surface 110c can form an upper surface, a bottom surface, and both side surfaces of the case 110.

As another example, the case 110 can be formed in a spherical or hemispherical shape, or can be formed in another polyhedral shape other than a hexahedron, such as a tetrahedron, and thus a shape of the case 110 is not limited to any one form.

Meanwhile, the second surface 110b can be formed by a cover 115 provided to be separable from the case 110. As one example, the case 110 can be formed by a combination of a case main body formed by the first surface 110a and the third surface 110c, and a cover 115 forming the second surface 110b.

The case main body including the first surface 110a and the third surface 110c can form a front surface, an upper surface, a bottom surface, and both side surfaces of the case 110, and the accommodation space S can be formed inside the case main body.

In the case main body, the other side in the first direction of the accommodation space S can be open. The other side in the first direction of the open accommodation space S can be covered by the cover 115 forming the second surface 110b.

The cover 115 can be detachably coupled to an end portion on the other side in the first direction of the case main body, and can form the second surface 110b of the case 110 in a state coupled to the case main body. In a state where the cover 115 is separated from the case main body, work of inserting components such as the camera module 130 and the fan 140 into the accommodation space S or taking them out from the accommodation space S can be performed.

A camera module 130 can be accommodated in the accommodation space S inside the case 110. The camera module 130 is provided to be capable of photographing still images and moving images. Such a camera module 130 is provided to be capable of photographing a peripheral area on one side in the first direction of the imaging device 100, i.e., a front peripheral area of the imaging device 100.

The camera module 130 may include an image processing unit 131. The image processing unit 131 may include one or more image sensors. As the image sensor, a CCD, a CMOS, or the like can be used.

As one example, the image sensor can be provided in a form mounted on a circuit board 133. At this time, the image sensor can be disposed on a front surface of the circuit board 133 facing the first surface 110a of the case 110.

Additionally, the camera module 130 may include a lens unit 135. The lens unit 135 may include at least one lens. As one example, the lens unit 135 can be provided in a form in which a plurality of lenses disposed along the first direction are accommodated in a barrel.

The lens unit 135 can be disposed between the first surface 110a of the case 110 and the circuit board 133. The lens unit 135 collects light reflected from a subject to form an optical image in an imaging area, and the image processing unit 131 can receive light incident through the lens unit 135 and convert it into an image signal.

In addition, the camera module 130 can further include various processors necessary to form an image based on the image signal output from the image processing unit 131, and can further include lighting composed of LEDs and the like.

Meanwhile, the case 110 may be provided with a penetrating portion 112. The penetrating portion 112 is provided on the first surface 110a and can be formed in a form penetrating a portion of the first surface 110a in the first direction.

The penetrating portion 112 may include a light transmission hole a. The light transmission hole a can form, in the first surface 110a, a passage required for light to pass through the first surface 110a and reach the camera module 130. As one example, the light transmission hole a can be formed to have a circular shape on a plane formed by the first surface 110a.

Such a light transmission hole a is disposed on a front side of the camera module 130 and can be disposed in an area overlapping with the camera module 130 in the front-rear direction. For example, light reflected from a subject can be incident to the lens unit 135 through the light transmission hole a and then transmitted to the image sensor through the lens unit 135.

Additionally, the penetrating portion 112 may include a discharge port b. Like the light transmission hole a, the discharge port b can form a passage penetrating the first surface 110a in the first direction. Such a discharge port b can form, in the first surface 110a, a passage for an air flow flowing in the first direction from the accommodation space S to pass through the first surface 110a in the first direction.

As one example, the discharge port b may be disposed so as to surround the light transmission hole a from a radially outer side thereof.

In the present embodiment, the radial direction is defined as a direction orthogonal to the first direction. Additionally, the radial center can be defined as the center of a circle formed by the light transmission hole a on the plane of the first surface 110a. Additionally, among the radial directions, a direction toward the center of the circle is defined as a centripetal direction, and a direction opposite to the centripetal direction can be defined as a centrifugal direction.

Additionally, the imaging device 100 can further include a fan 140. The fan 140 is provided to be capable of generating an air flow passing through the accommodation space S. As one example, the fan 140 can be accommodated in the accommodation space S. Such a fan 140 may draw air outside the case 110 into the accommodation space S and then discharge it through the discharge port b.

### Structure of Support Member

The imaging device 100 can further include a support member 120. The support member 120 is provided to be capable of accommodating at least a portion of the camera module 130. Such a support member 120 can be coupled to the camera module 130 and can support the camera module 130 on the case 110.

The support member 120 can be coupled to the first surface 110a of the case 110. As another example, the support member 120 can be integrally formed with the first surface 110a of the case 110. At least a portion of the support member 120 is disposed on a rear side of the first surface 110a and can be disposed in the accommodation space S.

Additionally, at least a portion of the support member 120 can be disposed to overlap with the penetrating portion 112 in the first direction. Accordingly, at least a portion of the support member 120 can be exposed to a front side of the case 110 through the penetrating portion 112.

The support member 120 may include fixing portions 121 and 122. The fixing portions 121 and 122 can be provided for coupling between the support member 120 and the case 110, more specifically, for coupling between the support member 120 and the first surface 110a.

The fixing portions 121 and 122 and the first surface 110a can be coupled in the first direction. As one example, the fixing portions 121 and 122 can be fixed to the first surface 110a in a form fitted to the first surface 110a. As another example, the fixing portions 121 and 122 and the first surface 110a can be integrally formed.

As one example, the fixing portions 121 and 122 may include a support surface 121 and a coupling protrusion 122.

The support surface 121 can form a plane parallel to the first surface 110a and can be disposed to face the first surface 110a in the first direction. The support surface 121 can be disposed on a rear side of the first surface 110a.

The coupling protrusion 122 can be provided to protrude from the support surface 121 in the first direction. Such a coupling protrusion 122 can protrude from the support surface 121 to one side in the first direction, i.e., forward. As one example, the coupling protrusion 122 can be formed in a form protruding forward from an edge of the support surface 121.

As one example, the coupling protrusion 122 can be coupled to the first surface 110a in a form fitted to the first surface 110a from a rear side of the first surface 110a. To this end, the first surface 110a can be formed with a fitting hole for fitting coupling between the first surface 110a and the coupling protrusion 122. As another example, the coupling protrusion 122 can be connected to the first surface 110a in a form integrally formed with the first surface 110a.

The light transmission hole a can be formed in a portion of the support surface 121. For example, the light transmission hole a can be provided in a portion of an area of the support surface 121 that overlaps with the penetrating portion 112 in the front-rear direction, and the light transmission hole a can be formed in a form in which a portion of the support surface 121 is penetrated in the first direction.

Additionally, the discharge port b can also be formed in a portion of the support surface 121. For example, the discharge port b can be provided in a portion of an area of the support surface 121 that overlaps with the penetrating portion 112 in the front-rear direction, and the discharge port b can be formed in a form in which a portion of the support surface 121 is penetrated in the first direction. Such a discharge port b can be disposed on a radially outer side of the light transmission hole a.

The support member 120 may include an outer tube portion 123. The outer tube portion 123 is provided to be capable of surrounding the light transmission hole a from a radially outer side thereof. Such an outer tube portion 123 may protrude from the support surface 121 in the first direction, and can be formed in a form of a short pipe with both sides in the first direction being open in the first direction. The light transmission hole a can be formed on a radially inner side of the outer tube portion 123 formed in this way. Additionally, the discharge port b can also be formed on a radially inner side of the outer tube portion 123.

Additionally, the support member 120 can further include an inner tube portion 125. The inner tube portion 125 can be disposed on a radially inner side of the outer tube portion 123. Such an inner tube portion 125 may protrude from the support surface 121 in the first direction, and can be formed in a pipe form with both sides in the first direction being open in the first direction.

For example, the outer tube portion 123 and the inner tube portion 125 can be disposed concentrically, and the light transmission hole a can be formed on a radially inner side of the inner tube portion 125.

Preferably, the inner tube portion 125 can be formed to protrude further toward the other side in the first direction, i.e., to the rear, than the outer tube portion 123. At least a portion of the camera module 130 can be accommodated inside such an inner tube portion 125.

As one example, the lens unit 135 can be accommodated inside the inner tube portion 125. Additionally, the image sensor can also be accommodated inside the inner tube portion 125.

In addition, the support member 120 can further include a fastening boss 127. Like the outer tube portion 123, the fastening boss 127 may protrude from the support surface 121 toward a rear side. As one example, the fastening boss 127 is disposed on a radially outer side of the inner tube portion 125 and can be disposed adjacent to the inner tube portion 125 and the circuit board 133. Such a fastening boss 127 can be provided for coupling between the camera module 130 and the support member 120.

As one example, in a state where the circuit board 133 and the fastening boss 127 are in contact in the first direction, coupling between the circuit board 133 and the fastening boss 127 can be achieved. Coupling between the circuit board 133 and the fastening boss 127 can be achieved by a fastening member such as a screw penetrating the circuit board 133 and the fastening boss 127 in the first direction.

Meanwhile, the discharge port b can be formed between the outer tube portion 123 and the inner tube portion 125. According to the present embodiment, the outer tube portion 123 and the inner tube portion 125 are disposed concentrically, and the outer tube portion 123 and the inner tube portion 125 are spaced apart by a predetermined distance in the radial direction. The discharge port b can be formed between the outer tube portion 123 and the inner tube portion 125 spaced apart in this way.

A guide vane 129 can be provided between the outer tube portion 123 and the inner tube portion 125. The guide vane 129 can be formed in a shape extending in the centrifugal direction from an outer circumferential surface of the inner tube portion 125, and can connect between the inner tube portion 125 and the outer tube portion 123.

The outer tube portion 123 is connected to the support surface 121, and the inner tube portion 125 can be connected to the outer tube portion 123 by the guide vane 129. A plurality of guide vanes 129 can be disposed between the outer tube portion 123 and the inner tube portion 125 to be spaced apart at predetermined intervals along a circumferential direction of the outer tube portion 123 or the inner tube portion 125.

Accordingly, under a condition in which the discharge port b is formed between the outer tube portion 123 and the inner tube portion 125, the inner tube portion 125 can be stably fixed to the outer tube portion 123 and the support surface 121 by the guide vane 129.

In addition, the guide vane 129 can also perform a role of guiding a discharge direction of air discharged through the discharge port b, in addition to a role of supporting the inner tube portion 125. That is, a discharge direction of air discharged through the discharge port b can be set according to an angle of a surface formed by the guide vane 129.

As one example, the guide vane 129 can guide the discharge direction of air passing through the discharge port b so that the air is concentrated toward one side in the first direction. Accordingly, air discharged through the discharge port b can flow in a form of moving straight toward one side in the first direction, i.e., forward, without spreading laterally.

Additionally, the imaging device 100 can further include a lens cover 150. The lens cover 150 is provided to be capable of covering the light transmission hole a and being coupled to the support member 120. More specifically, the lens cover 150 can be coupled to the inner tube portion 125 defining an outer boundary surface of the light transmission hole a.

The lens cover 150 can be provided to be capable of allowing light to pass therethrough. As one example, the lens cover 150 can be formed of a transparent glass or plastic material. Such a lens cover 150 is disposed to block the light transmission hole a and the camera module 130 from one side in the first direction to protect the camera module 130, and can allow light to pass through that should be incident to the camera module 130.

As described above, the support member 120 may be provided with structures related to installation and protection of the camera module 130 (inner tube portion, fastening boss) and structures for forming the light transmission hole a and the discharge port b (outer tube portion, inner tube portion, guide vane) together.

Preferably, the support member 120 can be provided in a form in which structures related to installation and protection of the camera module 130 and structures for forming the light transmission hole a and the discharge port b are integrally formed.

Additionally, the support member 120 can be formed separately from the case 110, and the camera module 130 and the lens cover 150 and the like can be coupled to the support member 120 in a state where the support member 120 is separated from the case 110. That is, in a state where the support member 120 is separated from the case 110, the camera module 130 and the lens cover 150 and the like can be installed on the support member 120 first, and in a state in which installation of the camera module 130, the lens cover 150, and the like has been completed in this way, coupling between the support member 120 and the case 110 can be achieved.

Thereby, not only can formation of the light transmission hole a and the discharge port b be achieved more easily at a lower cost, but also installation work of the camera module 130 and the like can be achieved more easily and effectively.

### Intake Port

As described above, the fan 140 can be accommodated in the accommodation space S inside the case 110. Such a fan 140 can generate an air flow passing through the first surface 110a in the first direction. For example, the fan 140 can draw in air from outside the case 110 into the accommodation space S and then discharge the air toward a front side of the imaging device 100 through the discharge port b.

Such a fan 140 can be disposed between the second surface 110b and the camera module 130. That is, with respect to the first direction, the fan 140 can be disposed between the second surface 110b and the camera module 130. Additionally, with respect to the first direction, it can also be expressed that the camera module 130 is disposed between the fan 140 and the discharge port b.

As one example, a small-sized axial fan can be applied as the fan 140. As another example, a centrifugal fan or a mixed flow fan can be applied as the fan 140, and thus a form of the fan 140 is not limited to any one form.

As described above, the first surface 110a may be provided with the discharge port b. Additionally, at least any one of the second surface 110b and the third surface 110c may be provided with an intake port, as illustrated in FIGS. 2 to 5. Hereinafter, an intake port provided on the second surface 110b is referred to as a first intake port c, and an intake port provided on the third surface 110c is referred to as a second intake port d.

The first intake port c can be provided on the second surface 110b and can form a passage penetrating the second surface 110b in the first direction. Such a first intake port c can form, on the second surface 110b, a passage necessary for an air flow flowing in the first direction in the accommodation space S to pass through the second surface 110b in the first direction.

The first intake port c is disposed on the rear side of the fan 140 and the camera module 130, and a plurality of first intake ports c can be disposed on the second surface 110b. As one example, the plurality of second intake ports d can be disposed over most areas of the second surface 110b.

According to the present embodiment, the first intake port c and the discharge port b can be arranged along the first direction. Additionally, the fan 140 can be disposed between the first intake port c and the discharge port b. That is, with respect to the first direction, the fan 140 can be disposed between the first intake port c and the discharge port b.

The second intake port d can be provided on the third surface 110c and can form a passage penetrating the third surface 110c in a direction orthogonal to the first direction. For example, the second intake port d can form a passage penetrating an upper surface or a bottom surface of the case 110 in an up-down direction or penetrating a side surface of the case 110 in a lateral direction on the side surface of the case 110.

Additionally, the second intake port d and the discharge port b can also be arranged along the first direction. Additionally, the fan 140 can be disposed between the second intake port d and the discharge port b. That is, with respect to the first direction, the fan 140 can be disposed between the second intake port d and the discharge port b.

Air outside the imaging device 100 is introduced into the accommodation space S through at least any one of the first intake port c and the second intake port d, and can be discharged to an outside of the imaging device 100 through the discharge port b, and can be discharged toward a front of the imaging device 100.

For example, as illustrated in FIG. 6, air outside the imaging device 100 can be sucked into the fan 140 through the first intake port c and discharged to an outside of the imaging device 100 through the discharge port b. At this time, a flow of air generated by the fan 140 can be a flow in a straight direction passing through the first intake port c, the fan 140, and the discharge port b in the first direction.

Additionally, as illustrated in FIG. 7, air outside the imaging device 100 can be sucked into the fan 140 through the second intake port d and discharged to an outside of the imaging device 100 through the discharge port b.

### Operation and Effect of Imaging Device

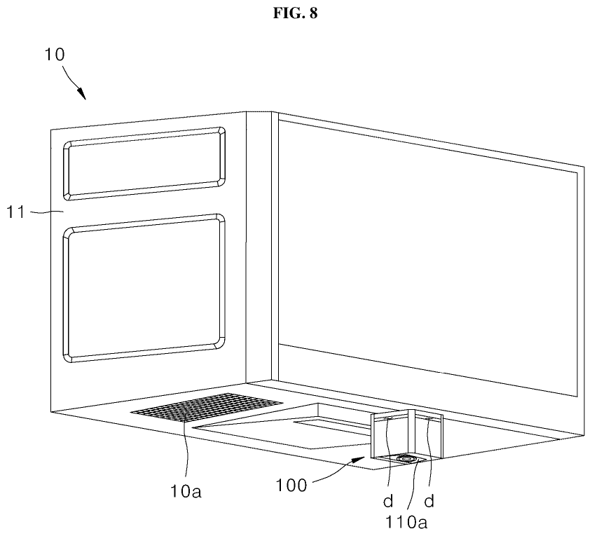

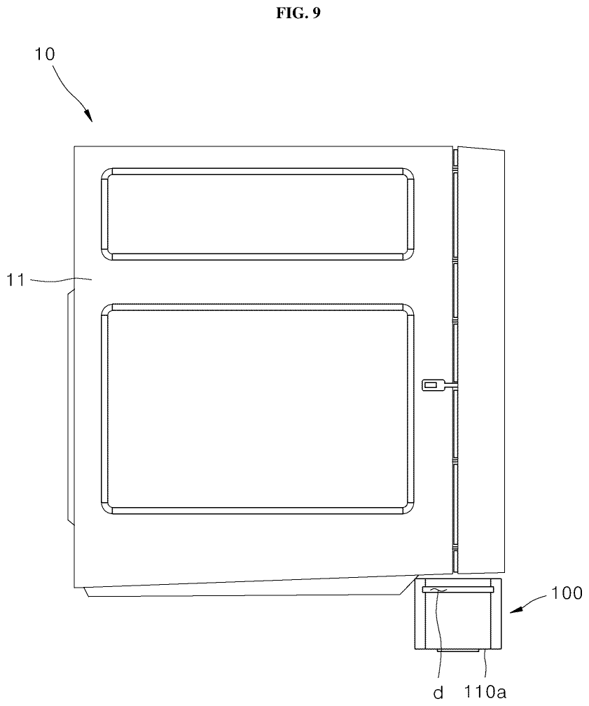

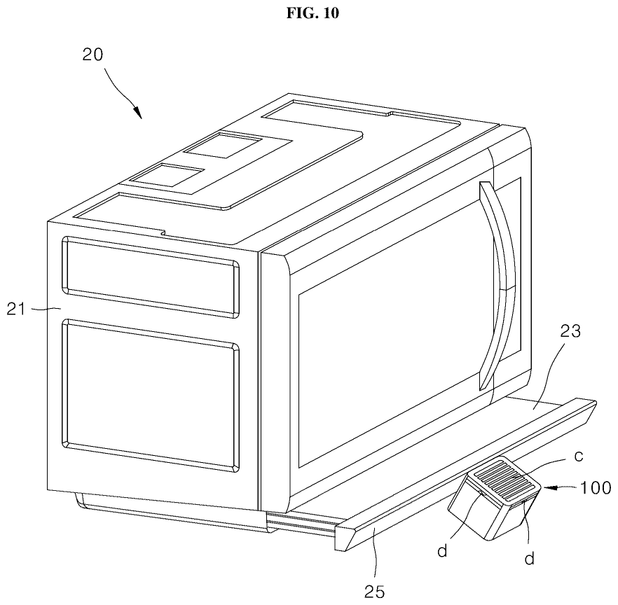

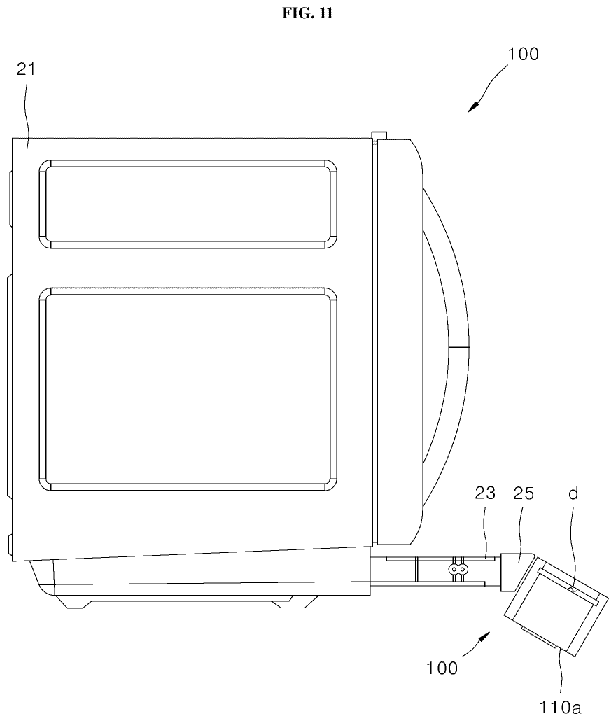

FIG. 8 is a perspective view showing one example in which an imaging device is installed in a home appliance, and FIG. 9 is a side view illustrating a side surface of the home appliance illustrated in FIG. 8. Additionally, FIG. 10 is a perspective view showing another example in which an imaging device is installed in a home appliance, and FIG. 11 is a side view illustrating a side surface of the home appliance illustrated in FIG. 10.

Referring to FIGS. 7 to 9, an imaging device 100 according to one embodiment of the present invention can be installed on a main body 11 of a home appliance disposed above a cooktop, for example, an over-the-range microwave oven 10.

A cooking chamber, which is a space for cooking food, and a heat source for heating the cooking chamber can be provided on the main body 11 of the over-the-range microwave oven 10.

Additionally, a blower unit that sucks contaminated air through an intake port 10a can be provided inside the main body 11 of the over-the-range microwave oven 10.

As another example, the imaging device 100 can be installed on a bottom surface of a hood device having only a hood function, i.e., a hood device having only a blower unit and an intake port without a cooking function. In this case, the main body of the home appliance can be the hood device.

In the present embodiment, an operation and effect of the imaging device will be described taking as an example a case where the imaging device 100 is installed on the main body 11 of the over-the-range microwave oven 10.

As one example, the imaging device 100 can be installed on a bottom surface of the over-the-range microwave oven 10. Additionally, the imaging device 100 can be disposed at a position adjacent to a front surface of the over-the-range microwave oven 10 on the bottom surface of the over-the-range microwave oven 10. For example, the imaging device 100 can be disposed at a lower front end of the over-the-range microwave oven 10.

The imaging device 100 disposed in this way can photograph a cooktop while looking down at the cooktop from above the cooktop. Additionally, the imaging device 100 can photograph the cooktop and a periphery thereof while looking down at the cooktop and a front side thereof from above the cooktop.

As one example, the imaging device 100 can be installed on the over-the-range microwave oven 10 such that the first surface 110a can face a photographing target area. For example, the imaging device 100 can be installed on the over-the-range microwave oven 10 such that the first surface 110a faces the cooktop and a front side thereof.

Accordingly, by disposing the light transmission hole a and the camera module 130 disposed on a rear side thereof to face the photographing target area, photographing of the photographing target area can be achieved by the camera module 130.

In this case, the first direction can be a direction between an up-down direction and a front-rear direction, and one side in the first direction can be a direction between a downward direction and a forward direction.

Contaminated air generated in a process of cooking on the cooktop can be sucked into an inside of the over-the-range microwave oven 10 through the intake port 10a. Contaminated air sucked into an inside of the over-the-range microwave oven 10 in this way can be discharged to an outside of the over-the-range microwave oven 10 through an exhaust port formed above the over-the-range microwave oven 10.

The intake port 10a can be disposed at a lower end of the over-the-range microwave oven 10. That is, the intake port 10a can be formed on the bottom surface of the over-the-range microwave oven 10. Such an intake port 10a can be disposed adjacent to the imaging device 100 installed on the bottom surface of the over-the-range microwave oven 10.

Accordingly, the imaging device 100 is disposed on a flow path of contaminated air flowing from the cooktop toward the intake port 10a. That is, the imaging device 100 is disposed at a position capable of contacting with a portion of contaminated air flowing toward the intake port 10a.

According to the present embodiment, the imaging device 100 is provided with a lens cover 150, and this lens cover 150 can block contaminated air from flowing into an inside of the imaging device 100 toward the camera module 130.

Additionally, the imaging device 100 is provided with a fan 140, and this fan 140 can generate an air flow (hereinafter referred to as “discharge air flow”) discharged toward a front of the imaging device 100 through the discharge port b.

A discharge air flow, which is a flow of air discharged through the discharge port b surrounding the periphery of the light transmission hole a, may prevent contaminated air from flowing toward the imaging device 100, particularly, toward the area where the light transmission hole a and the lens cover 150 are located.

That is, a discharge air flow generated by the imaging device 100 surrounds a periphery of the light transmission hole a and the lens cover 150 from an outer side and is discharged toward one side in the first direction, thereby blocking an area around the light transmission hole a and the lens cover 150 so that contaminated air cannot approach an area where the light transmission hole a and the lens cover 150 are located, and can induce a flow of contaminated air toward an outer side of the imaging device 100.

Accordingly, contaminated air becomes difficult to approach the imaging device 100, particularly, a periphery of the light transmission hole a and the lens cover 150, due to a discharge air flow discharged from the imaging device 100. Thereby, the imaging device 100 can be protected from contaminated air so as to be less affected by heat, water vapor, and oil vapor of contaminated air flowing around a home appliance on which the imaging device 100 is installed.

That is, the imaging device 100 of the present embodiment can block contaminated air from approaching the imaging device 100 by discharging a discharge air flow on a path through which contaminated air approaches the imaging device 100, and can protect the imaging device 100 from heat, water vapor, and oil vapor of contaminated air.

As one example, the imaging device 100 can be installed on the over-the-range microwave oven 10 in a form in which the second surface 110b is disposed to face the bottom surface of the over-the-range microwave oven 10. When it is said that no additional structure is added for coupling between the imaging device 100 and the over-the-range microwave oven 10, the imaging device 100 can be installed such that its second surface 110b is in close contact with the bottom surface of the over-the-range microwave oven 10.

In this case, the bottom surface of the over-the-range microwave oven 10 covers the first intake port c provided on the second surface 110b, and thus it becomes difficult to suck external air through the first intake port c.

In consideration of this point, in the present embodiment, a second intake port d can be further provided in addition to the first intake port c. Accordingly, even when the first intake port c is covered as described above, suction of air can be achieved through the second intake port d.

As such, the imaging device 100 of the present embodiment having the first intake port c and the second intake port d can be installed at any position on a home appliance regardless of the installation location, and can be mounted in any orientation regardless of the installation direction.

Referring to FIGS. 10 and 11, an imaging device 100 according to one embodiment of the present invention can be installed on an over-the-range microwave oven 20 having a slide-out module 23. In this over-the-range microwave oven 20, the slide-out module 23 can be operated in a manner of being pulled out forward from a main body 21 of the over-the-range microwave oven 20 or pushed in rearward. An intake port 20a can be provided on a bottom surface of the slide-out module 23.

Additionally, the intake port 20a can be formed on the bottom surface of the slide-out module 23.

A front frame 25 can be provided on a front side of the slide-out module 23. The front frame 25 forms a front exterior of the slide-out module 23 and is provided to be capable of being grasped by a user with a hand.

Since the slide-out module 23 is provided to be capable of entering and exiting an inside of the main body 21 of the over-the-range microwave oven 20, it is preferable that the imaging device 100 is installed on the front frame 25 rather than being installed on the bottom surface of the slide-out module 23.

In this case, the imaging device 100 can be installed on the slide-out module 23 in a form in which the third surface 110c is attached to the front frame 25. Accordingly, any one of the second intake ports d can be covered by the front frame 25, but air may be drawn in through the remaining second intake ports d as shown in FIG. 8, or through the first intake port c as shown in FIG. 7.

### Another Example of Imaging Device

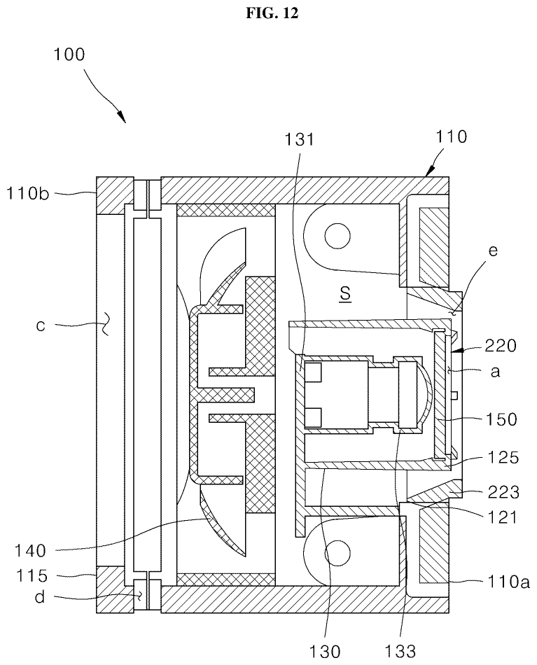

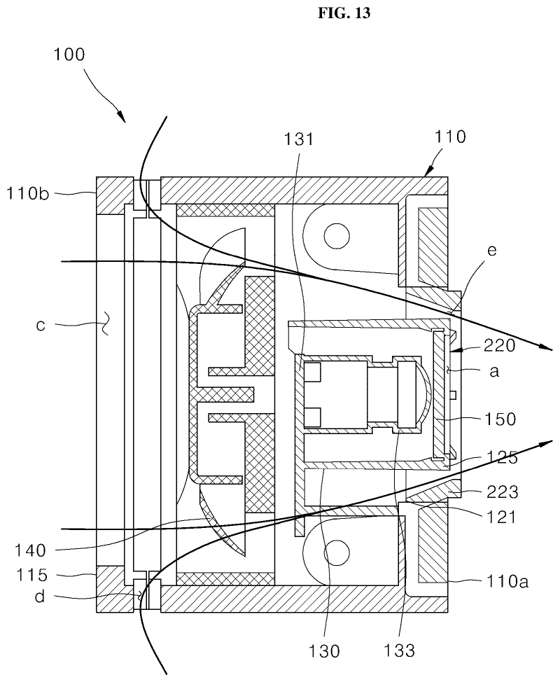

FIG. 12 is a cross-sectional view showing an internal structure of an imaging device according to another embodiment of the present invention, and FIG. 13 is a cross-sectional view showing another example of an air flow generated by the imaging device illustrated in FIG. 12.

Hereinafter, a structure and operation of an imaging device according to another embodiment of the present invention will be described with reference to FIGS. 12 to 13.

Referring to FIG. 12, in an imaging device 200 according to another embodiment of the present invention, a discharge port e may be formed in an inclined form.

To this end, an outer tube portion 223 provided on a support member 220 can be formed in an inclined form. As one example, the outer tube portion 223 can be formed such that an inside of the outer tube portion 223 narrows toward a center of the outer tube portion 223 toward one side in the first direction. In other words, the outer tube portion 223 can be formed such that an inside of the outer tube portion 223 narrows toward the inner tube portion 125 or the light transmission hole a toward one side in the first direction.

Additionally, the outer tube portion 223 can be formed such that an inner circumferential surface of the outer tube portion 223 is inclined toward a centripetal direction.

As the outer tube portion 223 is formed in a shape as described above, the discharge port e can form a passage in a form that becomes closer toward the light transmission hole a toward one side in the first direction.

As another example, an outer circumferential surface of the inner tube portion 125 can be formed to be inclined toward a centripetal direction like the inner circumferential surface of the outer tube portion 223. For example, an outer circumferential surface of the inner tube portion 125 facing the inner circumferential surface of the outer tube portion 223 can form an inclined surface parallel to the inner circumferential surface of the outer tube portion 223.

A discharge air flow that has passed through the discharge port e forming an inclined passage as described above can be discharged to be concentrated toward a peripheral area of the light transmission hole a, as illustrated in FIG. 13. Accordingly, contaminated air that was flowing in a direction toward the light transmission hole a is split around the discharge air flow and changes a flow direction to a direction away from the light transmission hole a.

Thereby, approach of contaminated air to an area where the light transmission hole a and the lens cover 150 are located can be blocked more effectively, and the imaging device 200 can be protected more effectively from contaminated air flowing around a home appliance on which the imaging device 200 is installed.

Although the invention has been described with reference to the embodiments illustrated in the drawings, this is merely exemplary, and it will be understood that various modifications and equivalent other embodiments are possible therefrom by one having ordinary skill in the art to which the invention pertains. Therefore, the true technical protection scope of the invention should be determined by the following claims.

### DESCRIPTION OF REFERENCE NUMERALS

10, 20: Over-the-range microwave oven
10a, 20a: Intake port
100: Imaging device
110: Case
110a: First surface
110b: Second surface
110c: Third surface
115: Cover
120: Support member
121: Support surface
122: Coupling protrusion
123: Outer tube portion
125: Inner tube portion
127: Fastening boss
129: Guide vane
130: Camera module
131: Image processing unit
133: Circuit board
135: Lens unit
140: Fan
150: Lens cover
a: Light transmission hole
b, e: Discharge port
c: First intake port
d: Second intake port
S: Accommodation space

1. An imaging device comprising:
a case forming an accommodation space therein;
a camera module accommodated in the accommodation space; and
a fan generating an air flow passing through the accommodation space,
wherein the case is provided with a first surface disposed on one side in a first direction of the accommodation space opening the accommodation space in the first direction, and
wherein the fan is configured to generate an air flow that passes through the first surface in the first direction.

2. The imaging device of claim 1, wherein the first surface is provided with a discharge port forming a passage penetrating the first surface in the first direction.

3. The imaging device of claim 2, wherein, with respect to the first direction, the camera module is disposed between the fan and the discharge port.

4. The imaging device of claim 2, further comprising an outer tube portion surrounding the discharge port from a radially outer side thereof,
wherein the outer tube portion is formed such that an inside of the outer tube portion narrows toward a radial center of the outer tube portion toward one side in the first direction, and
an inner circumferential surface of the outer tube portion is formed to be inclined toward a centripetal direction toward one side in the first direction.

5. The imaging device of claim 1, wherein the first surface is provided with a penetrating portion penetrating a portion of the first surface in the first direction, and
the penetrating portion includes a light transmission hole forming, in the first surface, a passage necessary for light to pass through the first surface and reach the camera module.

6. The imaging device of claim 5, wherein the penetrating portion includes a discharge port forming a passage penetrating the first surface in the first direction, and
on a plane orthogonal to the first direction, the discharge port is disposed on an outer side of the light transmission hole.

7. The imaging device of claim 6, further comprising:
an outer tube portion surrounding the light transmission hole from a radially outer side of the light transmission hole; and
an inner tube portion surrounding the light transmission hole from a radially outer side of the light transmission hole and disposed on a radially inner side of the outer tube portion,
wherein the discharge port is disposed between the inner tube portion and the outer tube portion.

8. The imaging device of claim 7, wherein the inner tube portion protrudes from the first surface toward the accommodation space in the first direction, and
at least a portion of the camera module is accommodated inside the inner tube portion.

9. The imaging device of claim 8, further comprising a lens cover covering the light transmission hole and coupled to the inner tube portion,
wherein the lens cover is provided to be capable of allowing light to pass therethrough.

10. The imaging device of claim 1, wherein the case is provided with a second surface disposed on the other side in the first direction of the accommodation space, and
the second surface is provided with an intake port forming a passage penetrating the second surface in the first direction.

11. The imaging device of claim 10, wherein the first surface is provided with a discharge port forming a passage penetrating the first surface in the first direction,
the intake port and the discharge port are arranged along the first direction, and
the fan is disposed between the intake port and the discharge port.

12. The imaging device of claim 1, wherein the case is provided with a second surface disposed on the other side in the first direction of the accommodation space, and a third surface connecting between the first surface and the second surface, and
the third surface is provided with an intake port forming a passage penetrating the third surface in a direction orthogonal to the first direction.

13. The imaging device of claim 12, wherein the first surface is provided with a discharge port forming a passage penetrating the first surface in the first direction,
the intake port and the discharge port are arranged along the first direction, and
the fan is disposed between the intake port and the discharge port.

14. The imaging device of claim 1, wherein the case is provided with a second surface disposed on the other side in the first direction of the accommodation space, and a third surface connecting between the first surface and the second surface,
the second surface is provided with a first intake port forming a passage penetrating the second surface in the first direction, and
the third surface is provided with a second intake port forming a passage penetrating the third surface in a direction orthogonal to the first direction.

15. A home appliance comprising:
a main body; and
the imaging device of claim 1 coupled to the main body.

16. The home appliance of claim 15, wherein the case is provided with a second surface disposed on the other side in the first direction of the accommodation space, and a third surface connecting between the first surface and the second surface,
the second surface is provided with a first intake port forming a passage penetrating the second surface in the first direction,
the third surface is provided with a second intake port forming a passage penetrating the third surface in a direction orthogonal to the first direction, and
the second surface or the third surface is coupled to a bottom surface of the main body.
